(19) United States
(12) Patent Application Publication
(10) Pub. No.: US 2026/0221070 A1
(43) Pub. Date: Jul. 30, 2026

(54) SHIFT REGISTER AND DRIVING METHOD, GATE DRIVING CIRCUIT, AND DISPLAY PANEL AND APPARATUS

(71) Applicants: HEFEl BOE JOINT TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(72) Inventors: Xuehuan Feng, Beijing (CN); Yongqian Li, Beijing (CN)

(73) Assignees: HEFEl BOE JOINT TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(21) Appl. No.: 19/146,761

(22) PCT Filed: Jun. 14, 2024
(86) PCT No.: PCT/CN2024/099400

§ 371 Date: Jul. 9, 2025

(30) Foreign Application Priority Data
Jul. 28, 2023 (CN) 202310943578.X

(51) Int. Cl. G09G 3/20; G09G 3/32; G09G 3/3266; G09G 3/36; G11C 19/28

(52) U.S. Cl. CPC G09G 3/2074; G09G 3/32; G09G 3/3266; G09G 3/3677; G09G 2310/0267; G09G 2310/0286; G09G 2310/08; G11C 19/287

(57) ABSTRACT

A shift register and a driving method thereof, a display panel and a displaying device. The shift register includes an inputting circuit, an isolating circuit, a resetting circuit, a first controlling circuit and an outputting circuit. The inputting circuit is electrically connected to an input terminal, a first clock-signal terminal and a first node. The isolating circuit is electrically connected to the first node, a second node and a second clock-signal terminal. The resetting circuit is electrically connected to a first voltage terminal, an output terminal and the second node. The first controlling circuit is electrically connected to a fourth node, a fourth clock-signal terminal, a third voltage terminal, the first node, a fourth voltage terminal and a fifth node. The outputting circuit is electrically connected to a fifth voltage terminal, the output terminal and the fifth node.

The present application claims the priority of the Chinese patent application filed on Jul. 28, 2023 before the Chinese Patent Office with the application number of 202310943578.X and the title of “SHIFT REGISTER AND DRIVING METHOD, GATE DRIVING CIRCUIT, AND DISPLAY PANEL AND APPARATUS”, which is incorporated herein in its entirety by reference.

### TECHNICAL FIELD

The present disclosure relates to the technical field of displaying, and particularly relates to a shift register and a driving method, a gate driving circuit, a display panel and a displaying device.

### BACKGROUND

Scanning driving circuits are an auxiliary circuit in display panels, and can drive line by line the pixels within the displaying region to emit light. A scanning driving circuit comprises a plurality of shift registers. In operation, the output terminal of the shift register easily has the problem of output instability.

### SUMMARY

The embodiments of the present disclosure provide a shift register and a driving method, a gate driving circuit, a display panel and a displaying device, which enables the signal outputted by the output terminal of the shift register to be more stable.

In order to achieve the above object, the embodiments of the present disclosure employ the following technical solutions:

In an aspect, there is provided a shift register, wherein the shift register comprises an inputting circuit, an isolating circuit, a resetting circuit, a first controlling circuit and an outputting circuit;
the inputting circuit is electrically connected to an input terminal, a first clock-signal terminal and a first node, and the inputting circuit is configured for, under controlling by a signal of the first clock-signal terminal, writing a signal of the input terminal into the first node;
the isolating circuit is electrically connected to the first node, a second node and a second clock-signal terminal, and the isolating circuit is configured for, under controlling by a signal of the second clock-signal terminal, connecting or disconnecting a path between the first node and the second node;
the resetting circuit is electrically connected to a first voltage terminal, an output terminal and the second node, and the resetting circuit is configured for, under controlling by a signal of the second node, writing an electrical level of the first voltage terminal into the output terminal;
the first controlling circuit is electrically connected to a fourth node, a fourth clock-signal terminal, a third voltage terminal, the first node, a fourth voltage terminal and a fifth node, and the first controlling circuit is configured for, under controlling by signals of the fourth node and the fourth clock-signal terminal, writing an electrical level of the third voltage terminal into the fifth node; or, under controlling by the signal of the first node, writing an electrical level of the fourth voltage terminal into the fifth node; and
the outputting circuit is electrically connected to a fifth voltage terminal, the output terminal and the fifth node, and the outputting circuit is configured for, under controlling by a signal of the fifth node, writing an electrical level of the fifth voltage terminal into the output terminal.

In some embodiments, the isolating circuit comprises a storing sub-circuit and a switch sub-circuit;
the storing sub-circuit is electrically connected to the first node, and the storing sub-circuit is configured for storing the signal of the first node; and
the switch sub-circuit is electrically connected to the second clock-signal terminal, the first node and the second node, and the switch sub-circuit is configured for, under controlling by the signal of the second clock-signal terminal, connecting or disconnecting the path between the first node and the second node.

In some embodiments, the switch sub-circuit comprises an eleventh transistor; and
a control electrode of the eleventh transistor is electrically connected to the second clock-signal terminal, a first electrode of the eleventh transistor is electrically connected to the second node, and a second electrode of the eleventh transistor is electrically connected to the first node.

In some embodiments, the storing sub-circuit comprises a fourth capacitor, and a first polar plate of the fourth capacitor is electrically connected to the first node.

In some embodiments, the shift register further comprises a second controlling circuit, the second controlling circuit is electrically connected to a fifth clock-signal terminal, the fourth node, a sixth voltage terminal and the first node, and the second controlling circuit is configured for, under controlling by signals of the fifth clock-signal terminal and the fourth node, writing an electrical level of the sixth voltage terminal into the first node.

In some embodiments, the second controlling circuit comprises a fifth transistor and a sixth transistor;
a control electrode of the fifth transistor is electrically connected to the fifth clock-signal terminal, a first electrode of the fifth transistor is electrically connected to the first node, and a second electrode of the fifth transistor is electrically connected to a third node; and
a control electrode of the sixth transistor is electrically connected to the fourth node, a first electrode of the sixth transistor is electrically connected to the third node, and a second electrode of the sixth transistor is electrically connected to the sixth voltage terminal.

In some embodiments, the shift register further comprises a second controlling circuit, the second controlling circuit is electrically connected to a fifth clock-signal terminal, the fourth node, a sixth voltage terminal and the second node, and the second controlling circuit is configured for, under controlling by signals of the fifth clock-signal terminal and the fourth node, writing an electrical level of the sixth voltage terminal into the second node.

In some embodiments, the second controlling circuit comprises a fifth transistor and a sixth transistor;
a control electrode of the fifth transistor is electrically connected to the fifth clock-signal terminal, a first electrode of the fifth transistor is electrically connected to the second node, and a second electrode of the fifth transistor is electrically connected to a third node; and
a control electrode of the sixth transistor is electrically connected to the fourth node, a first electrode of the sixth transistor is electrically connected to the third node, and a second electrode of the sixth transistor is electrically connected to the sixth voltage terminal.

In some embodiments, the shift register further comprises a third controlling circuit, the third controlling circuit is electrically connected to a third clock-signal terminal, the first node, a second voltage terminal and the fourth node, and the third controlling circuit is configured for, under controlling by a signal of the third clock-signal terminal, writing an electrical level of the second voltage terminal into the fourth node; or, under controlling by the signal of the first node, writing a signal of the third clock-signal terminal into the fourth node.

In some embodiments, the third controlling circuit comprises a second transistor and a fourth transistor;
a control electrode of the second transistor is electrically connected to the third clock-signal terminal, a first electrode of the second transistor is electrically connected to the second voltage terminal, and a second electrode of the second transistor is electrically connected to the fourth node; and
a control electrode of the fourth transistor is electrically connected to the first node, a first electrode of the fourth transistor is electrically connected to the third clock-signal terminal, and a second electrode of the fourth transistor is electrically connected to the fourth node.

In some embodiments, the inputting circuit comprises a first transistor, a control electrode of the first transistor is electrically connected to the first clock-signal terminal, a first electrode of the first transistor is electrically connected to the first node, and a second electrode of the first transistor is electrically connected to the input terminal.

In some embodiments, the resetting circuit comprises an eighth transistor and a third capacitor;
a control electrode of the eighth transistor is electrically connected to the second node, a first electrode of the eighth transistor is electrically connected to the first voltage terminal, and a second electrode of the eighth transistor is electrically connected to the output terminal; and
a first polar plate of the third capacitor is electrically connected to the second node, and a second polar plate of the third capacitor is electrically connected to the second clock-signal terminal, the first voltage terminal or the output terminal.

In some embodiments, the outputting circuit comprises a tenth transistor and a second capacitor;
a control electrode of the tenth transistor is electrically connected to the fifth node, a first electrode of the tenth transistor is electrically connected to the output terminal, and a second electrode of the tenth transistor is electrically connected to the fifth voltage terminal; and
a first polar plate of the second capacitor is electrically connected to the fifth node, and a second polar plate of the second capacitor is electrically connected to the fifth voltage terminal.

In some embodiments, the first controlling circuit comprises a third transistor, a seventh transistor and a first capacitor;
a control electrode of the third transistor is electrically connected to the fourth node, a first electrode of the third transistor is electrically connected to a sixth node, and a second electrode of the third transistor is electrically connected to the third voltage terminal;
a control electrode of the seventh transistor is electrically connected to the fourth clock-signal terminal, a first electrode of the seventh transistor is electrically connected to the sixth node, and a second electrode of the seventh transistor is electrically connected to the fifth node; and
a first polar plate of the first capacitor is electrically connected to the fourth node, and a second polar plate of the first capacitor is electrically connected to the second clock-signal terminal.

In another aspect, there is provided a driving method of a shift register, for driving the shift register stated above, an operation cycle of the shift register comprises a first stage, a second stage, a third stage, a fourth stage and a fifth stage, and the driving method comprises:
at the first stage, supplying signals to the first clock-signal terminal and the second clock-signal terminal, whereby a first electrical level of the input terminal is written into the first node, and the path between the first node and the second node is disconnected;
at the second stage and the third stage, supplying signals to the first clock-signal terminal and the second clock-signal terminal, whereby the first node and the second node are connected, and an electrical level of the first node is written into the second node;
at the fourth stage, supplying signals to the first clock-signal terminal and the second clock-signal terminal, whereby a second electrical level of the input terminal is written into the first node, and the path between the first node and the second node is disconnected; and
at the fifth stage, supplying a signal to the second clock-signal terminal, whereby the path between the first node and the second node is connected, and the electrical level of the first node is written into the second node;
wherein the first electrical level is greater than the second electrical level.

In yet another aspect, there is provided a gate driving circuit, wherein the gate driving circuit comprises a plurality of instances of the shift register stated above, and the plurality of shift registers are cascaded sequentially.

In yet another aspect, there is provided a display panel, wherein the display panel comprises the gate driving circuit stated above.

In still another aspect, there is provided a displaying device, wherein the displaying device comprises the display panel stated above.

In the shift register and the driving method thereof, the gate driving circuit, the display panel and the displaying device according to the embodiments of the present disclosure, at the first stage, the high-level signal of the input terminal is written into the first node, and the second node, by the effect of the isolating circuit, is disconnected from the first node, whereby the electrical level of the second node is not influenced by the first node, and the second node can maintain the low-level signal written in the preceding period. Therefore, the first outputting circuit is controlled, so that the electrical level of the first voltage terminal is written into the output terminal, to prevent floating of the output terminal at the first stage, which increases the output stability of the shift register.

### BRIEF DESCRIPTION OF THE DRAWINGS

In order to more clearly illustrate the technical solutions of the embodiments of the present disclosure or the prior art, the figures that are required to describe the embodiments or the prior art will be briefly described below. Apparently, the figures that are described below are merely embodiments of the present disclosure, and a person skilled in the art can obtain other figures according to these figures without paying creative work.

FIG. 1 schematically shows a front structural diagram of a displaying device;

FIG. 2 schematically shows a schematic diagram of a display panel;

FIG. 3 schematically shows a circuit diagram of a pixel driving circuit;

FIG. 4 is a circuit diagram of a shift register in the related art;

FIG. 5 is an operation sequence diagram of the shift register shown in FIG. 4;

FIG. 6 is potential simulation diagrams of the nodes of the shift register shown in FIG. 4 in the operation process;

FIG. 7 schematically shows a circuit block diagram of a shift register;

FIG. 8 schematically shows a circuit block diagram of another shift register;

FIG. 9 schematically shows a circuit diagram of a shift register;

FIG. 10 schematically shows a circuit diagram of another shift register;

FIG. 11 schematically shows a circuit diagram of another shift register;

FIG. 12 schematically shows a circuit diagram of another shift register;

FIG. 13 schematically shows a circuit diagram of another shift register;

FIG. 14 schematically shows an operation sequence diagram of a shift register;

FIG. 15 is level simulation diagrams of the nodes of the shift register shown in FIG. 13 in the operation process; and

FIG. 16 schematically shows a block diagram of the steps of a driving method of a shift register.

### DETAILED DESCRIPTION

The technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the embodiments of the present disclosure, terms such as “first”, “second”, “third” and “fourth” are used to distinguish identical items or similar items that have substantially the same functions and effects, merely in order to clearly describe the technical solutions of the embodiments of the present disclosure, and should not be construed as indicating or implying the degrees of importance or implicitly indicating the quantity of the specified technical features.

In the embodiments of the present disclosure, the meaning of “plurality of” is “two or more”, and the meaning of “at least one” is “one or more”, unless explicitly and particularly defined otherwise.

In the embodiments of the present disclosure, the terms that indicate orientation or position relations, such as “upper” and “lower”, are based on the orientation or position relations shown in the drawings, and are merely for conveniently describing the present disclosure and simplifying the description, rather than indicating or implying that the device or element must have the specific orientation and be constructed and operated according to the specific orientation. Therefore, they should not be construed as a limitation on the present disclosure.

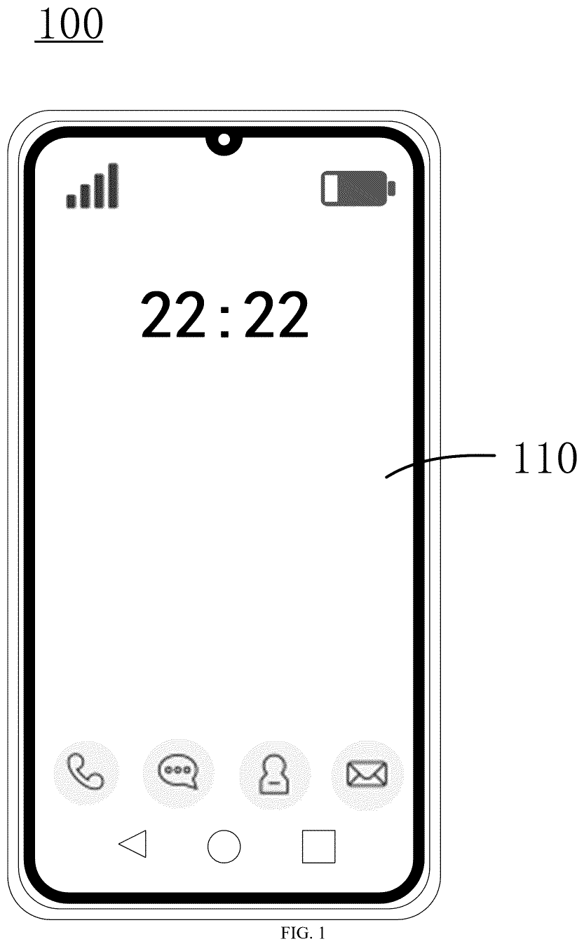

FIG. 1 schematically shows a front structural diagram of a displaying device. As shown in FIG. 1, some embodiments of the present disclosure provide a displaying device 100. The displaying device 100 may be any device that displays a moving (for example, a video) or fixed (for example, a stationary image) text or image. For example, the displaying device 100 may be a mobile phone, a wireless device, a personal data assistant (PDA), a hand-held or portable computer, a GPS receiver/navigator, a camera, an MP4 video player, a video camera, a game console, a watch, a clock, a computer, a television monitor, a flat-panel display, a computer monitor, a vehicle display (for example, an odometer display), a navigator, a cockpit controller and/or display, a camera view display (for example, the display of a rear view camera of a vehicle), an electronic photograph, an electronic billboard or indicator, a projector, an architectural structure, and a packaging and aesthetics device (for example, a display for the image of a jewel). FIG. 1 illustrates by taking the case as an example in which the displaying device 100 is a mobile phone.

The displaying device 100 comprises a display panel 110. The display panel 110 may be a liquid-crystal display panel (Liquid Crystal Display, referred to for short as LCD). The display panel 110 may also be an electroluminescent display panel or a photoluminescent display panel. If the display panel 110 is an electroluminescent display panel, the electroluminescent display panel may be an organic electroluminescent (Organic Light Emitting Diode, referred to for short as OLED) display panel or a quantum-dot electroluminescent (Quantum-Dot Light Emitting Diode, referred to for short as QLED) display panel. If the display panel 110 is a photoluminescent display panel, the photoluminescent displaying device may be a quantum-dot photoluminescent display panel.

Some embodiments of the present disclosure illustrate by taking the case as an example in which the flexible display panel 110 is an organic light emitting diode (referred to for short as OLED) display panel.

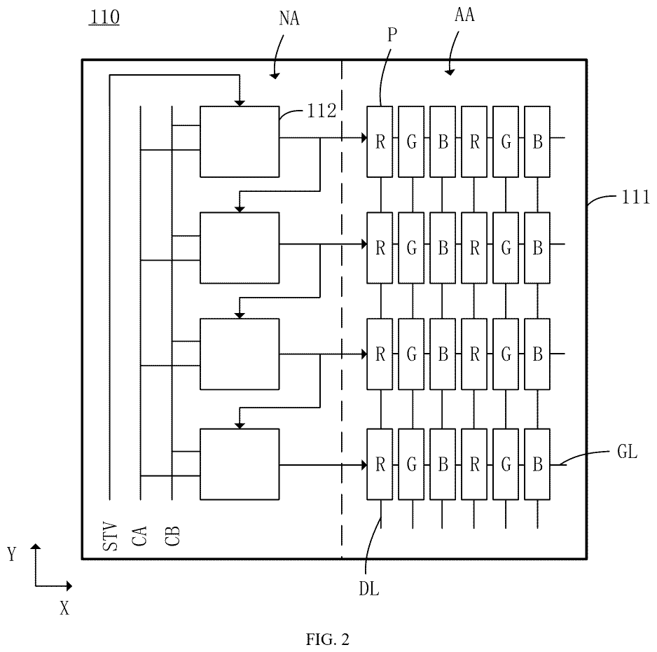

FIG. 2 schematically shows a schematic diagram of a display panel. As shown in FIG. 2, the display panel 110 comprises a substrate 111, and a plurality of sub-pixels P, a plurality of grid lines GL and a plurality of data lines DL that are provided on one side of the substrate 111.

The substrate 111 may be a rigid substrate, and may also be a flexible substrate, which may be selected and configured according to practical demands.

As an example, the substrate 111 may be a rigid substrate. For example, the rigid substrate may be a glass substrate, a PMMA (Polymethyl Methacrylate) substrate and so on.

As an example, the substrate 111 may be a flexible substrate. For example, the flexible substrate may be a PET (Polyethylene Terephthalate) substrate, a PEN (Polyethylene Naphthalate) substrate, a PI (Polyimide) substrate and so on.

The display panel 110 may have a displaying region AA and a non-displaying region NA electrically connected to the displaying region AA. The non-displaying region NA may be located on one side, two sides or three sides of the displaying region AA, or the non-displaying region NA may surround the displaying region AA. The plurality of sub-pixels P, the plurality of grid lines GL and the plurality of data lines DL may be located within the displaying region AA.

As an example, the plurality of sub-pixels P may be arranged in an array. For example, the plurality of sub-pixels P, when arranged in an array, form a plurality of sub-pixel rows and a plurality of sub-pixel columns, wherein the plurality of sub-pixels P in each of the sub-pixel rows are arranged in a first direction X, and the plurality of sub-pixels P in each of the sub-pixel columns are arranged in a second direction Y.

The first direction X and the second direction Y intersect with each other. The included angle between the first direction X and the second direction Y may be selected and configured according to practical demands. As an example, the included angle between the first direction X and the second direction Y may be 85°, 88°, 90°, 92°, 95° and so on.

Each of the sub-pixels P may comprise a pixel driving circuit and a light emitting device electrically connected to the pixel driving circuit. When the display panel 110 is operating, the light emitting device may emit light by the driving by the pixel driving circuit.

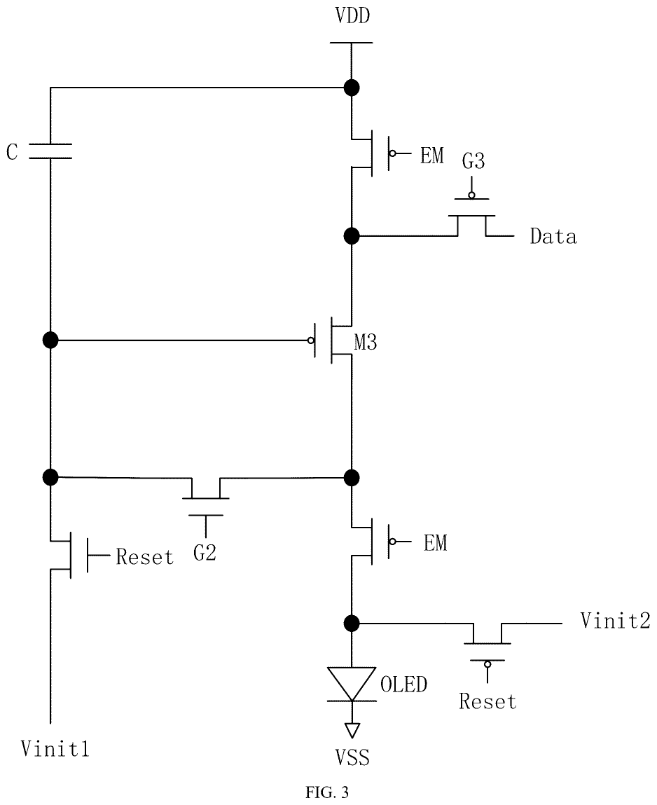

FIG. 3 schematically shows a circuit diagram of a pixel driving circuit. As shown in FIG. 3, the pixel driving circuit comprises a light-emission controlling terminal EM, a data-signal terminal Data, a data-writing controlling terminal Gate and a resetting controlling terminal Reset. The light-emission controlling terminal EM, the data-signal terminal Data, the data-writing controlling terminal Gate and the resetting controlling terminal Reset of the pixel driving circuit may receive signals, and, under the controlling by the signals, drive the light emitting device OLED to emit light.

FIG. 3 illustrates by taking the case as an example in which the pixel driving circuit is of the structure 7T1C. In practical applications, the pixel driving circuit may also be other structures such as 4T1C, 6T1C, 6T2C, 7T2C and 8T2C, and the structure of the pixel driving circuit is not limited in the embodiments of the present disclosure. T represents the transistors, the number preceding T represents the quantity of the transistors, C represents the capacitors, and the number preceding C represents the quantity of the capacitors.

As an example, the plurality of pixel driving circuits in the same one sub-pixel column may be electrically connected to the same one data line DL, and the plurality of pixel driving circuits in the same one sub-pixel row may be electrically connected to the same one grid line GL. For example, the grid lines include a first grid line, a second grid line and a third grid line, the first grid line is electrically connected to the light-emission controlling terminals EM of the pixel driving circuits in the same one sub-pixel row, the second grid line is electrically connected to the data-writing controlling terminals Gate of the pixel driving circuits in the same one sub-pixel row, and the third grid line is electrically connected to the resetting controlling terminals Reset of the pixel driving circuits in the same one sub-pixel row. The quantity of the grid lines that are electrically connected to the plurality of pixel driving circuits in the same one sub-pixel row may be set according to the structures of the pixel driving circuits.

Referring continuously to FIG. 2, a scanning driving circuit is provided on one side of the substrate 111. The scanning driving circuit comprises a plurality of shift registers 112 that are cascaded. Each of the shift registers 112 comprises an output terminal. The output terminals of the shift registers 112 may be electrically connected to the grid lines GL. When the scanning driving circuit is operating, the plurality of cascaded shift registers 112 output signals with levels to the pixel driving circuit by using the output terminals.

The output terminals of the shift registers 112 may be electrically connected to at least one of the light-emission controlling terminals EM, the data-writing controlling terminals Gate and the resetting controlling terminals Reset of the pixel driving circuits via the grid lines GL.

The embodiments of the present disclosure illustrate by taking the case merely as an example in which the output terminals of the shift registers 112 are electrically connected to the light-emission controlling terminals EM of the pixel driving circuits via the grid lines GL.

As an example, the scanning driving circuit is provided within the non-displaying region NA. Certainly, in practical applications, in order to reduce the size of the border frame of the display panel 110, at least part of the scanning driving circuit may also be provided within the displaying region AA.

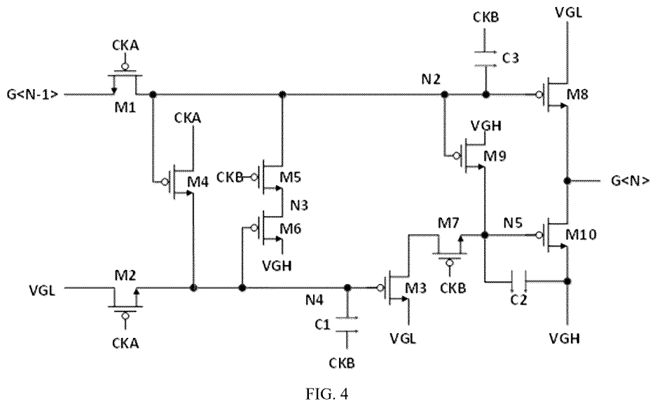

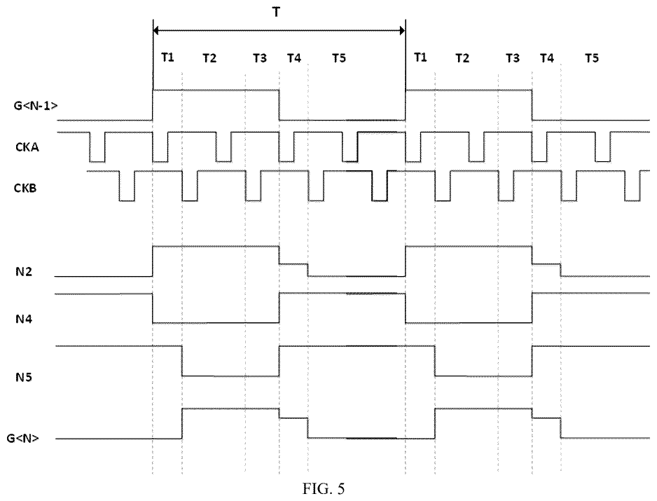

FIG. 4 is a circuit diagram of a shift register in the related art. All of the transistors shown in FIG. 4 are a P-type transistor. The terminal VGH is applied with a high-level signal, and the terminal VGL is applied with a low-level signal. FIG. 5 is an operation sequence diagram of the shift register shown in FIG. 4. The time-sequence signal labeled as G<N−1> is applied into the terminal G<N−1> in FIG. 4. The time-sequence signal labeled as CKA is applied into the terminals CKA in FIG. 4. The time-sequence signal labeled as CKB is applied into the terminals CKB in FIG. 4. The time-sequence signal labeled as G<N> is the signal outputted by the output terminal G<N> in FIG. 4. FIG. 6 is potential simulation diagrams of the nodes of the shift register shown in FIG. 4 in the operation process.

The operation process of the shift register in the related art will be described in detail below with reference to FIGS. 4 to 6.

As shown in FIG. 5, the operation process of the shift register in the related art comprises a plurality of operation cycles T, and each of the operation cycles T comprises a stage T1. Taking one of the operation cycles T as an example, at the stage T1, in the terminal G<N−1> there is a high-level signal, in the terminal CKA there is a low-level signal, and in the terminal CKB there is a high-level signal. The transistor M1 is switched on under the controlling by the low-level signal of the terminal CKA, the high-level signal of the terminal G<N−1> is written into the node N2 via the transistor M1, and the transistor M8 is turned off under the controlling by the high-level signal of the node N2. The transistor M7 is turned off under the controlling by the high-level signal of the terminal CKB, the transistor M9 is turned off under the controlling by the high-level signal of the node N2, and the node N5 maintains the high-level signal of the preceding operation cycle by the effect of the capacitor C2, to cause the transistor M10 to be turned off. When the transistor M8 and the transistor M10 are in the off-state simultaneously, the terminal G<N> is not conducted with VGL and VGH; in other words, the terminal G<N> is in the floating state. In this case, the output of the shift register is unstable, and the signal of the terminal G<N> is susceptible to external interference and thus varies.

In view of the above, an embodiment of the present disclosure provides a shift register, which ameliorates instability of the output of the output terminal of the shift register.

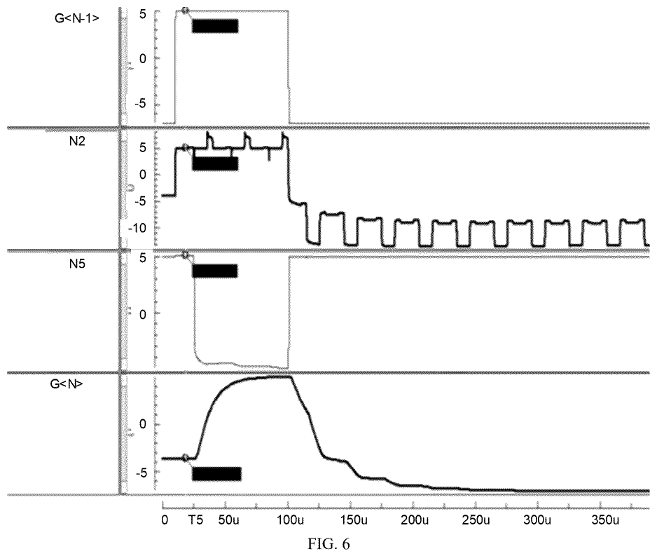

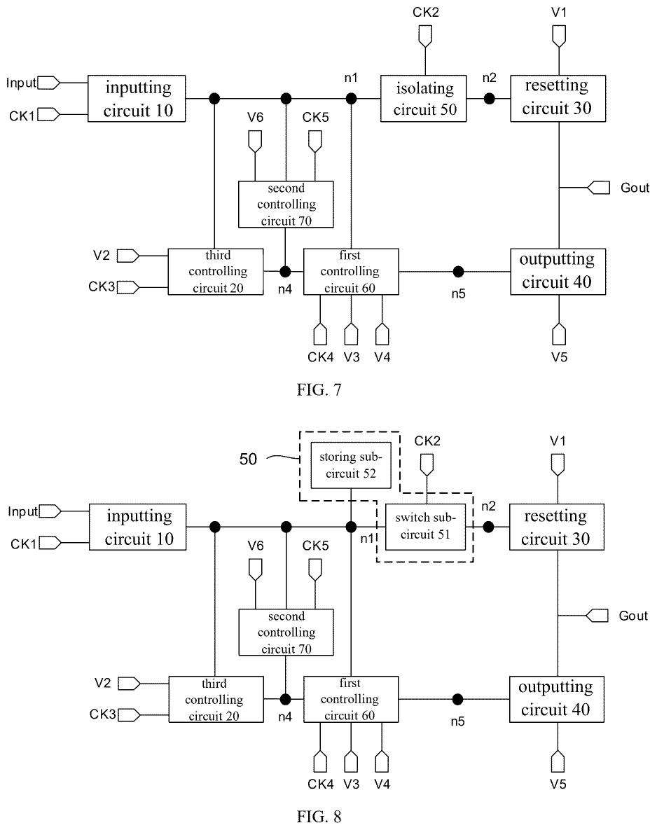

FIG. 7 schematically shows a circuit block diagram of a shift register. As shown in FIG. 7, the shift register comprises an inputting circuit 10, an isolating circuit 50, a resetting circuit 30, a first controlling circuit 60 and an outputting circuit 40.

The inputting circuit 10 is electrically connected to an input terminal Input, a first clock-signal terminal CK1 and a first node n1. The inputting circuit 10 is configured for, under the controlling by the signal of the first clock-signal terminal CK1, writing the signal of the input terminal Input into the first node n1.

The input terminal Input may be electrically connected to a start-signal line. For example, the scanning driving circuit comprises a start-signal line, and a plurality of shift registers that are cascaded sequentially, and the input terminal Input of the first shift register is electrically connected to the start-signal line, to receive a start signal in the start-signal line.

The input terminal Input may also be electrically connected to the output terminal Gout of another shift register. For example, the scanning driving circuit comprises a plurality of shift registers that are cascaded sequentially, and the input terminal Input of the n-th shift register is electrically connected to the output terminal Gout of the (n−1)-th shift register, wherein n>1.

The scanning driving circuit further comprises a clock-signal line, and the first clock-signal terminal CK1 may be electrically connected to the clock-signal line, to receive a clock signal in the clock-signal line. For example, the scanning driving circuit comprises a plurality of clock-signal lines that extend in a second direction Y, the plurality of clock-signal lines include a first clock-signal line CA, and the first clock-signal terminal CK1 is electrically connected to the first clock-signal line CA.

The first node n1 does not refer to a component that actually exists, but refers to a convergence point of the relevant electric connections in the circuit diagram. In other words, the first node n1 refers to a node equivalent to the convergence point of the relevant electric connections in the circuit diagram. Likewise, all of the second node n2, the third node n3, the fourth node n4 and the fifth node n5 according to the embodiments of the present disclosure refer to nodes equivalent to the convergence points of the relevant electric connections in the circuit diagram.

As an example, when the signal of the first clock-signal terminal CK1 is a low-level signal, the input terminal Input and the first node n1 are conducted with each other, and the signal of the input terminal Input is written into the first node n1 via the inputting circuit 10. When the signal of the first clock-signal terminal CK1 is a high-level signal, the input terminal Input and the first node n1 are disconnected from each other.

The isolating circuit 50 is electrically connected to the first node n1, a second node n2 and a second clock-signal terminal CK2. The isolating circuit 50 is configured for, under the controlling by the signal of the second clock-signal terminal CK2, connecting or disconnecting the path between the first node n1 and the second node n2.

The second clock-signal terminal CK2 may be electrically connected to a clock-signal line, to receive a clock signal in the clock-signal line. For example, the plurality of clock-signal lines include a second clock-signal line CB, and the second clock-signal terminal CK2 is electrically connected to the second clock-signal line CB. The second clock-signal line CB and the first clock-signal line CA are two different clock-signal lines, and the signal in the second clock-signal line CB and the signal in the first clock-signal line CA are different. For example, when in the second clock-signal line CB there is a low-level signal, in the first clock-signal line CA there is a high-level signal, and when in the first clock-signal line CA there is a low-level signal, in the second clock-signal line CB there is a high-level signal.

As an example, when the signal of the second clock-signal terminal CK2 is a low-level signal, the first node n1 and the second node n2 are conducted with each other. When the signal of the second clock-signal terminal CK2 is a high-level signal, the first node n1 and the second node n2 are disconnected from each other.

FIG. 8 schematically shows a circuit block diagram of another shift register. As shown in FIG. 8, the isolating circuit 50 may comprise a storing sub-circuit 52 and a switch sub-circuit 51.

The switch sub-circuit 51 is electrically connected to the second clock-signal terminal CK2, the first node n1 and the second node n2, and the switch sub-circuit 51 is configured for, under the controlling by the signal of the second clock-signal terminal CK2, connecting or disconnecting the path between the first node n1 and the second node n2.

The storing sub-circuit 52 is electrically connected to the first node n1, and the storing sub-circuit 52 is configured for storing the signal of the first node n1. By storing the signal of the first node n1 by using the storing sub-circuit 52, the signal of the first node n1 is more stable.

The resetting circuit 30 is electrically connected to the second node n2, a first voltage terminal V1 and an output terminal Gout. The resetting circuit 30 is configured for, under the controlling by the signal of the second node n2, writing the electrical level of the first voltage terminal V1 into the output terminal Gout.

The shift register outputs the signal via the output terminal Gout. The output terminal Gout may be electrically connected to the grid line GL within the displaying region AA, to supply the signal to the pixel driving circuit via the grid line GL. The output terminal Gout may also be, at the same time, electrically connected to the input terminal Input of another shift register. For example, the scanning driving circuit comprises a plurality of shift registers that are cascaded sequentially, and the output terminal Gout of the n-th shift register is electrically connected to the input terminal Input of the (n+1)-th shift register, wherein n>1.

The first voltage terminal V1 may be applied with a constant electrical level; for example, the first voltage terminal V1 is applied with a constant low level. As an example, the display panel comprises a first voltage line VGL, the first voltage line VGL is applied with a constant low level, and the first voltage line VGL is electrically connected to the first voltage terminal V1.

As an example, when the signal of the second node n2 is a low-level signal, the first voltage terminal V1 and the output terminal Gout are conducted with each other, the electrical level of the first voltage terminal V1 is written into the output terminal Gout via the resetting circuit 30. When the signal of the second node n2 is a high-level signal, the first voltage terminal V1 and the output terminal Gout are disconnected from each other.

The first controlling circuit 60 is electrically connected to a fourth node n4, a fourth clock-signal terminal CK4, a third voltage terminal V3, a fifth node n5, the first node n1 and a fourth voltage terminal V4. The first controlling circuit 60 is configured for, under the controlling by the signals of the fourth node n4 and the fourth clock-signal terminal CK4, writing the electrical level of the third voltage terminal V3 into the fifth node n5; and under the controlling by the signal of the first node n1, writing the electrical level of the fourth voltage terminal V4 into the fifth node n5.

The third voltage terminal V3 may be applied with a constant electrical level; for example, the third voltage terminal V3 is applied with a constant low level. The electrical level of the third voltage terminal V3 may be the same as those of the first voltage terminal V1 and the second voltage terminal V2. As an example, both of the first voltage terminal V1 and the third voltage terminal V3 are electrically connected to the first voltage line VGL.

The fourth voltage terminal V4 may be applied with a constant electrical level; for example, the fourth voltage terminal V4 is applied with a constant high level. The electrical level of the fourth voltage terminal V4 is different from those of the first voltage terminal V1 and the third voltage terminal V3. As an example, the display panel further comprises a second voltage line VGH, the second voltage line VGH is applied with a constant high level, and the fourth voltage terminal V4 is electrically connected to the second voltage line VGH.

The fourth clock-signal terminal CK4 may be electrically connected to a clock-signal line, to receive a clock signal in the clock-signal line. The signal of the fourth clock-signal terminal CK4 may be the same as the signal of the second clock-signal terminal CK2. For example, both of the second clock-signal terminal CK2 and the fourth clock-signal terminal CK4 are electrically connected to the second clock-signal line CB.

As an example, when both of the signals of the fourth clock-signal terminal CK4 and the fourth node n4 are a low-level signal, the fourth voltage terminal V4 and the fifth node n5 are conducted with each other, and the electrical level of the third voltage terminal V3 is written into the fifth node n5. When in one or two of the fourth signal terminal and the fourth node n4 there is a high-level signal, the third voltage terminal V3 and the fifth node n5 are disconnected from each other. When the signal of the first node n1 is a low-level signal, the fourth voltage terminal V4 and the fifth node n5 are conducted with each other, and the electrical level of the fourth voltage terminal V4 is written into the fifth node n5. When the signal of the first node n1 is a high-level signal, the fourth voltage terminal V4 and the fifth node n5 are disconnected from each other.

The outputting circuit 40 is electrically connected to the fifth node n5, a fifth voltage terminal V5 and the output terminal Gout. The outputting circuit 40 is configured for, under the controlling by the signal of the fifth node n5, writing the electrical level of the fifth voltage terminal V5 into the output terminal Gout.

The fifth voltage terminal V5 may be applied with a constant electrical level; for example, the fifth voltage terminal V5 is applied with a constant high level. The electrical level of the fifth voltage terminal V5 may be the same as the electrical level of the fourth voltage terminal V4. As an example, both of the fourth voltage terminal V4 and the fifth voltage terminal V5 are electrically connected to the second voltage line VGH.

As an example, when the signal of the fifth node n5 is a low-level signal, the fifth voltage terminal V5 and the output terminal Gout are conducted with each other, and the electrical level of the fifth voltage terminal V5 is written into the output terminal Gout. When the signal of the fifth node n5 is a high-level signal, the fifth voltage terminal V5 and the output terminal Gout are disconnected from each other.

In the shift register according to the embodiments of the present disclosure, at a stage of the operation cycle, the high-level signal of the input terminal Input is written into the first node n1, and the second node n2, by the effect of the isolating circuit 50, is disconnected from the first node n1, whereby the electrical level of the second node n2 is not influenced by the first node n1, and the second node n2 can maintain the low-level signal written in the preceding period. Therefore, the first outputting circuit 40 is controlled, so that the electrical level of the first voltage terminal V1 is written into the output terminal Gout, to prevent floating of the output terminal Gout at the first stage, which increases the output stability of the shift register.

Referring continuously to FIG. 7, the shift register may further comprise a second controlling circuit 70. The second controlling circuit 70 is electrically connected to the fourth node n4, a fifth clock-signal terminal CK5, a sixth voltage terminal V6 and the first node n1. The second controlling circuit 70 is configured for, under the controlling by the signals of the fifth clock-signal terminal CK5 and the fourth node n4, writing the electrical level of the sixth voltage terminal V6 into the first node n1.

The sixth voltage terminal V6 may be applied with a constant electrical level; for example, the sixth voltage terminal V6 is applied with a constant high level. The electrical level of the sixth voltage terminal V6 may be the same as the electrical levels of the fourth voltage terminal V4 and the fifth voltage terminal V5. As an example, all of the fourth voltage terminal V4, the fifth voltage terminal V5 and the sixth voltage terminal V6 are electrically connected to the second voltage line VGH.

The fifth clock-signal terminal CK5 may be electrically connected to a clock-signal line, to receive a clock signal in the clock-signal line. The signal of the fifth clock-signal terminal CK5 may be the same as the signal of the second clock-signal terminal CK2. For example, all of the second clock-signal terminal CK2, the fourth clock-signal terminal CK4 and the fifth clock-signal terminal CK5 are electrically connected to the second clock-signal line CB.

As an example, when both of the signals of the fourth node n4 and the fifth clock-signal terminal CK5 are a low-level signal, the sixth voltage terminal V6 and the first node n1 are conducted with each other, and the electrical level of the sixth voltage terminal V6 is written into the first node n1. When the signal of one or two of the fourth node n4 and the fifth clock-signal terminal CK5 is a high-level signal, the sixth voltage terminal V6 and the first node n1 are disconnected from each other.

Alternatively, the second controlling circuit 70 is electrically connected to the fourth node n4, a fifth clock-signal terminal, a sixth voltage terminal V6 and the second node n2. The second controlling circuit 70 is configured for, under the controlling by the signals of the fifth clock-signal terminal CK5 and the fourth node n4, writing the electrical level of the sixth voltage terminal V6 into the second node n2.

As an example, when both of the signals of the fourth node n4 and the fifth clock-signal terminal CK5 are a low-level signal, the sixth voltage terminal V6 and the second node n2 are conducted with each other, and the electrical level of the sixth voltage terminal V6 is written into the second node n2. When the signal of one or two of the fourth node n4 and the fifth clock-signal terminal CK5 is a high-level signal, the sixth voltage terminal V6 and the second node n2 are disconnected from each other.

Referring continuously to FIG. 7, the shift register may further comprise a third controlling circuit 20, and the third controlling circuit 20 is electrically connected to a third clock-signal terminal CK3, a second voltage terminal V2, the fourth node n4 and the first node n1. The third controlling circuit 20 is configured for, under the controlling by the signal of the third clock-signal terminal CK3, writing the electrical level of the second voltage terminal V2 into the fourth node n4; or, under the controlling by the signal of the first node n1, writing the signal of the third clock-signal terminal CK3 into the fourth node n4.

The second voltage terminal V2 may be applied with a constant electrical level; for example, the second voltage terminal V2 is applied with a constant low level. The electrical level of the second voltage terminal V2 may be the same as the electrical level of the first voltage terminal V1. As an example, both of the first voltage terminal V1 and the second voltage terminal V2 are electrically connected to the first voltage line VGL.

The third clock-signal terminal CK3 may be electrically connected to a clock-signal line, to receive a clock signal in the clock-signal line. The signal of the third clock-signal terminal CK3 may be the same as the signal of the first clock-signal terminal CK1. For example, both of the first clock-signal terminal CK1 and the third clock-signal terminal CK3 are electrically connected to the first clock-signal line CA.

As an example, when the signal of the third clock-signal terminal CK3 is a low-level signal, the second voltage terminal V2 and the fourth node n4 are conducted with each other, and the electrical level of the second voltage terminal V2 is written into the fourth node n4 via the third controlling circuit 20. When the signal of the first node n1 is a low-level signal, the third clock-signal terminal CK3 and the fourth node n4 are conducted with each other, and the signal of the third clock-signal terminal CK3 is written into the fourth node n4 via the third controlling circuit 20. When the signal of the third clock-signal terminal CK3 is a high-level signal, the second voltage terminal V2 and the fourth node n4 are disconnected from each other. When the signal of the first node n1 is a high-level signal, the third clock-signal terminal CK3 and the fourth node n4 are disconnected from each other.

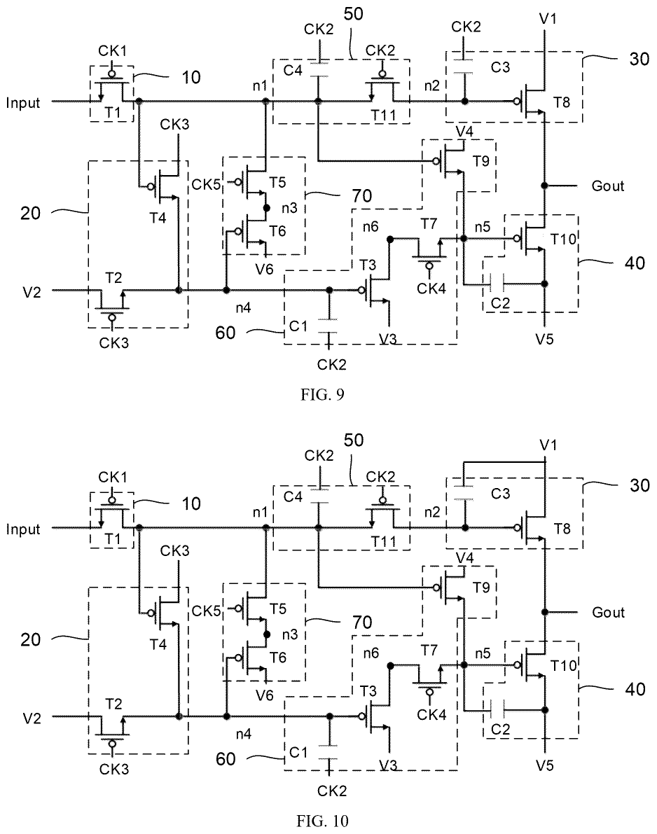

FIG. 9 schematically shows a circuit diagram of a shift register. The circuit structure of the shift register will be described in detail below with reference to FIG. 9.

As shown in FIG. 8, the shift register comprises a plurality of transistors, the first electrode of each of the transistors refers to one of the source and the drain of the transistor, and the second electrode refers to the other of the source and the drain of the transistor. Because the source and the drain of a transistor may be symmetrical in the structures, its source and drain may be not different in the structures; in other words, the first electrode and the second electrode of the transistors according to the embodiments of the present disclosure may be not different in the structures. The control electrode of each of the transistors may be the grid of the transistor, and the grid is used to control the turning-on or turning-off of the transistor. The shift register according to some embodiments of the present disclosure is illustrated by taking the case merely as an example in which all of the transistors are a P-type transistor.

The inputting circuit 10 may comprise a first transistor T1. The control electrode of the first transistor T1 is electrically connected to the first clock-signal terminal CK1, the first electrode of the first transistor T1 is electrically connected to the first node n1, and the second electrode of the first transistor T1 is electrically connected to the input terminal Input.

As an example, when the signal of the first clock-signal terminal CK1 is a low-level signal, the first transistor T1 is turned on, and the input terminal Input and the first node n1 are conducted with each other. When the signal of the first clock-signal terminal CK1 is a high-level signal, the first transistor T1 is turned off, and the input terminal Input and the first node n1 are disconnected from each other.

The switch sub-circuit 51 may comprise an eleventh transistor T11. The control electrode of the eleventh transistor T11 is electrically connected to the second clock-signal terminal CK2, the first electrode of the eleventh transistor T11 is electrically connected to the second node n2, and the second electrode of the eleventh transistor T11 is electrically connected to the first node n1.

As an example, when the signal of the second clock-signal terminal CK2 is a low-level signal, the eleventh transistor T11 is turned on, and the second node n2 and the first node n1 are conducted with each other. When the signal of the second clock-signal terminal CK2 is a high-level signal, the first transistor T1 is turned off, the second node n2 and the first node n1 are disconnected from each other.

The storing sub-circuit 52 may comprise a fourth capacitor C4, and a first polar plate of the fourth capacitor C4 is electrically connected to the first node n1. The second polar plate of the fourth capacitor C4 may be electrically connected to the second clock-signal terminal CK2, and may also be electrically connected to another voltage terminal.

In practical applications, a parasitic capacitor may be formed inside the eleventh transistor T11, and one of the polar plates of the parasitic capacitor is electrically connected to the first node n1, thereby storing the signal of the first node n1 by using the parasitic capacitor. For example, the gate of the eleventh transistor T11 and the active layer of the eleventh transistor T11 form the parasitic capacitor therebetween.

The resetting circuit 30 comprises an eighth transistor T8. The control electrode of the eighth transistor T8 is electrically connected to the second node n2, the first electrode of the eighth transistor T8 is electrically connected to the first voltage terminal V1, and the second electrode of the eighth transistor T8 is electrically connected to the output terminal Gout.

As an example, when the signal of the second node n2 is a low-level signal, the eighth transistor T8 is turned on, and the first voltage terminal V1 and the output terminal Gout are conducted with each other. When the signal of the second node n2 is a high-level signal, the eighth transistor T8 is turned off, and the first voltage terminal V1 and the output terminal Gout are disconnected from each other.

The resetting circuit 30 may further comprise a third capacitor C3. A first polar plate of the third capacitor C3 is electrically connected to the second node n2, and a second polar plate of the third capacitor C3 may be electrically connected to the second clock-signal terminal CK2.

In practical applications, a parasitic capacitor may be formed inside the eighth transistor T8, and one of the polar plates of the parasitic capacitor is electrically connected to the second node n2, thereby storing the signal of the second node n2 by using the parasitic capacitor. For example, the gate of the eighth transistor T8 and the active layer of the eighth transistor T8 form the parasitic capacitor therebetween.

FIG. 10 schematically shows a circuit diagram of another shift register. As shown in FIG. 10, the second polar plate of the third capacitor C3 may also be electrically connected to the first voltage terminal V1.

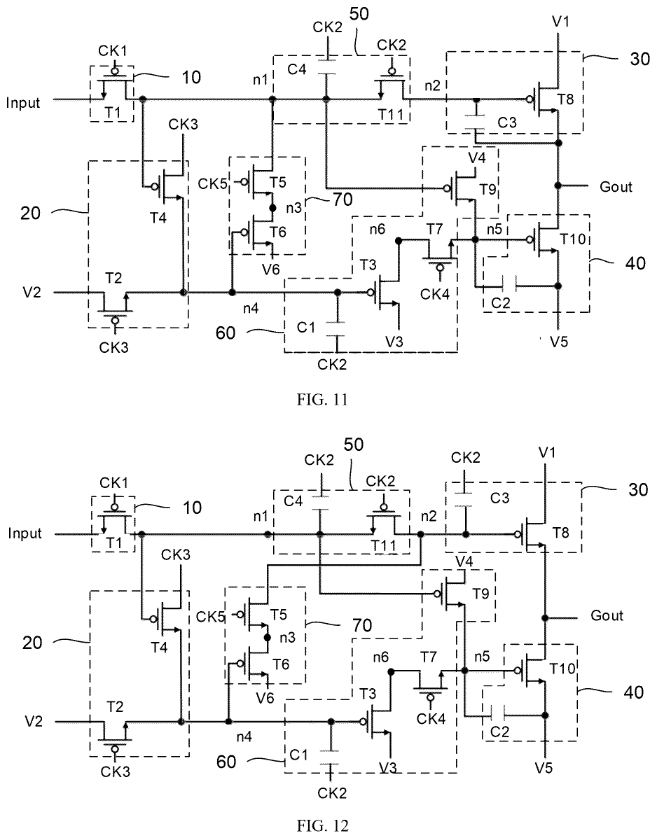

FIG. 11 schematically shows a circuit diagram of another shift register. As shown in FIG. 11, the second polar plate of the third capacitor C3 may also be electrically connected to the output terminal Gout. As an example, when the eighth transistor T8 is turned on, the low-level signal of the first voltage terminal V1 is written into the output terminal Gout, so that the electrical level of the second polar plate of the third capacitor C3 is reduced. Because the voltage between the two polar plates of the capacitor cannot suddenly change, the electrical level of the first polar plate of the third capacitor C3 is also reduced. In other words, the electrical level of the second node n2 is reduced, so that the eighth transistor T8 maintains the on-state, thereby realizing the function of bootstrapping by using the third capacitor C3.

The first controlling circuit 60 may comprise a third transistor T3, a seventh transistor T7, a ninth transistor T9 and a first capacitor C1. The control electrode of the third transistor T3 is electrically connected to the fourth node n4, the first electrode of the third transistor T3 is electrically connected to a sixth node n6, and the second electrode of the third transistor T3 is electrically connected to the third voltage terminal V3. The control electrode of the seventh transistor T7 is electrically connected to the fourth clock-signal terminal CK4, the first electrode of the seventh transistor T7 is electrically connected to the sixth node n6, and the second electrode of the seventh transistor T7 is electrically connected to the fifth node n5. The control electrode of the ninth transistor T9 is electrically connected to the first node n1, the first electrode of the ninth transistor T9 is electrically connected to the fourth voltage terminal V4, and the second electrode of the ninth transistor T9 is electrically connected to the fifth node n5. A first polar plate of the first capacitor C1 is electrically connected to the fourth node n4, and a second polar plate of the first capacitor C1 is electrically connected to the second clock-signal terminal CK2.

In practical applications, a parasitic capacitor may be formed inside the third transistor T3, and one of the polar plates of the parasitic capacitor is electrically connected to the fourth node n4, thereby storing the signal of the fourth node n4 by using the parasitic capacitor. For example, the gate of the third transistor T3 and the active layer of the third transistor T3 form the parasitic capacitor therebetween.

As an example, when both of the signals of the fourth node n4 and the fourth clock-signal terminal CK4 are a low-level signal, the third transistor T3 and the seventh transistor T7 are turned on, and the third voltage terminal V3 and the fifth node n5 are conducted with each other. When the signal of the first node n1 is a low-level signal, the ninth transistor T9 is turned on, and the fourth voltage terminal V4 and the fifth node n5 are conducted with each other.

The outputting circuit 40 may comprise a tenth transistor T10 and a second capacitor C2. The control electrode of the tenth transistor T10 is electrically connected to the fifth node n5, the first electrode of the tenth transistor T10 is electrically connected to the output terminal Gout, and the second electrode of the tenth transistor T10 is electrically connected to the fifth voltage terminal V5. A first polar plate of the second capacitor C2 is electrically connected to the fifth node n5, and a second polar plate of the second capacitor C2 is electrically connected to the fifth voltage terminal V5.

In practical applications, a parasitic capacitor may be formed inside the tenth transistor T10, and one of the polar plates of the parasitic capacitor is electrically connected to the fifth node n5, thereby storing the signal of the fifth node n5 by using the parasitic capacitor. For example, the gate of the tenth transistor T10 and the active layer of the tenth transistor T10 form the parasitic capacitor therebetween.

As an example, when the signal of the fifth node n5 is a low-level signal, the tenth transistor T10 is turned on, and the fifth voltage terminal V5 and the output terminal Gout are conducted with each other.

Referring continuously to FIGS. 9 to 11, the second controlling circuit 70 may comprise a fifth transistor T5 and a sixth transistor T6. The control electrode of the fifth transistor T5 is electrically connected to the fifth clock-signal terminal CK5, the first electrode of the fifth transistor T5 is electrically connected to the first node n1, and the second electrode of the fifth transistor T5 is electrically connected to a third node n3. The control electrode of the sixth transistor T6 is electrically connected to the fourth node n4, the first electrode of the sixth transistor T6 is electrically connected to the third node n3, and the second electrode of the sixth transistor T6 is electrically connected to the sixth voltage terminal V6.

As an example, when both of the signals of the fifth clock-signal terminal CK5 and the fourth node n4 are a low-level signal, the fifth transistor T5 and the sixth transistor T6 are turned on, and the sixth voltage terminal V6 and the first node n1 are conducted with each other.

FIG. 12 schematically shows a circuit diagram of another shift register. As shown in FIG. 12, the control electrode of the fifth transistor T5 is electrically connected to the fifth clock-signal terminal CK5, the first electrode of the fifth transistor T5 is electrically connected to the second node n2, and the second electrode of the fifth transistor T5 is electrically connected to a third node n3. The control electrode of the sixth transistor T6 is electrically connected to the fourth node n4, the first electrode of the sixth transistor T6 is electrically connected to the third node n3, and the second electrode of the sixth transistor T6 is electrically connected to the sixth voltage terminal V6.

As an example, when both of the signals of the fifth clock-signal terminal CK5 and the fourth node n4 are a low-level signal, the fifth transistor T5 and the sixth transistor T6 are turned on, and the sixth voltage terminal V6 and the second node n2 are conducted with each other.

The third controlling circuit 20 may comprise a second transistor T2 and a fourth transistor T4. The control electrode of the second transistor T2 is electrically connected to the third clock-signal terminal CK3, the first electrode of the second transistor T2 is electrically connected to the second voltage terminal V2, and the second electrode of the second transistor T2 is electrically connected to the fourth node n4. The control electrode of the fourth transistor T4 is electrically connected to the first node n1, the first electrode of the fourth transistor T4 is electrically connected to the third clock-signal terminal CK3, and the second electrode of the fourth transistor T4 is electrically connected to the fourth node n4.

As an example, when the signal of the third clock-signal terminal CK3 is a low-level signal, the second transistor T2 is turned on, and the second voltage terminal V2 and the fourth node n4 are conducted with each other. When the signal of the first node n1 is a low-level signal, the fourth transistor T4 is turned on, and the third clock-signal terminal CK3 and the fourth node n4 are conducted with each other.

The operation process of the shift register will be described below by taking the case merely as an example in which the first electrode of the fifth transistor T5 is electrically connected to the first node n1.

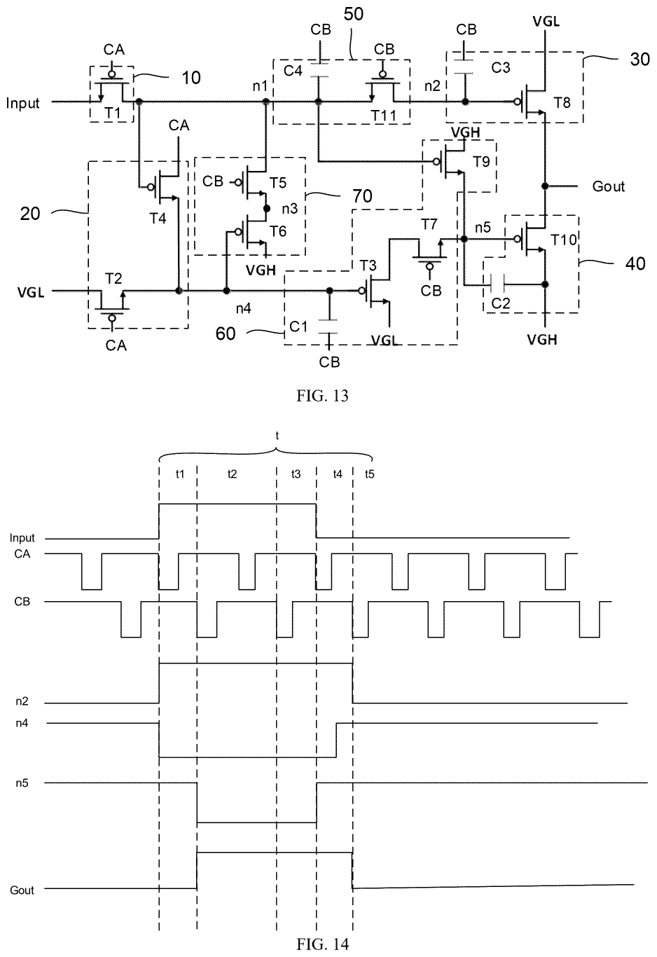

The first clock-signal terminal CK1 and the third clock-signal terminal CK3 may be electrically connected to the first clock-signal line CA, and the second clock-signal terminal CK2, the fourth clock-signal terminal CK4 and the fifth clock-signal terminal CK5 may be electrically connected to the second clock-signal line CB. The first voltage terminal V1, the second voltage terminal V2 and the third voltage terminal V3 may be electrically connected to the first voltage line VGL, and the fourth voltage terminal V4, the fifth voltage terminal V5 and the sixth voltage terminal V6 may be electrically connected to the second voltage line VGH. In this case, the circuit diagram of the shift register shown in FIG. 9 is as shown in FIG. 13.

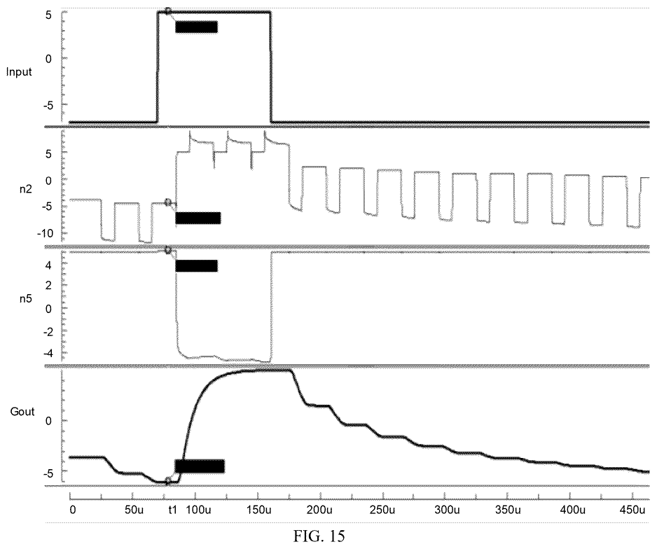

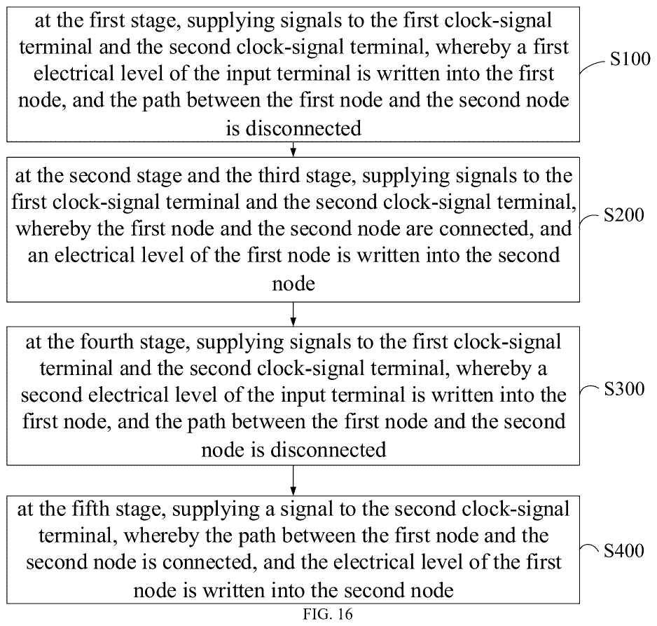

FIG. 14 schematically shows an operation sequence diagram of a shift register. In FIG. 14, the time-sequence signal labeled as Input is the signal of the input terminal Input, the time-sequence signal labeled as CA is the signal of the first clock-signal line CA, the time-sequence signal labeled as CB is the signal of the second clock-signal line CB, the time-sequence signal labeled as n2 is the signal of the second node n2, the time-sequence signal labeled as n4 is the signal of the fourth node n4, the time-sequence signal labeled as n5 is the signal of the fifth node n5, and the time-sequence signal labeled as Gout is the signal of the output terminal Gout. FIG. 15 is level simulation diagrams of the nodes of the shift register shown in FIG. 13 in the operation process.

The operation process of the shift register according to the embodiments of the present disclosure will be described in detail below with reference to FIGS. 13 to 15.

As shown in FIG. 14, the operation process of the shift register comprises a plurality of periods t, wherein the duration of the period t may be the duration during which the display panel displays one frame of image. The plurality of periods t include a first period and a second period that are consecutive. Each of the first period and the second period comprises a first stage t1, a second stage t2, a third stage t3, a fourth stage t4 and a fifth stage t5.

Within the first period:

At the first stage t1, in the input terminal Input there is a high-level signal, in the first clock-signal line CA there is a low-level signal, and in the second clock-signal line CB there is a high-level signal. The second transistor T2 is turned on, and the low-level signal of the second voltage terminal V2 is written into the fourth node n4, and stored in the first capacitor C1.

At the second stage t2, in the input terminal Input there is a high-level signal, in the first clock-signal line CA there is a high-level signal, and in the second clock-signal line CB there is a low-level signal. The second transistor T2 is turned off, and the fourth node n4 maintains the low level by the effect of the first capacitor C1, to cause the third transistor T3 and the sixth transistor T6 to be turned on. The fifth transistor T5 is turned on, and the high-level signal of the sixth voltage terminal V6 is written into the first node n1, and stored in the fourth capacitor C4. The eleventh transistor T11 is turned on, and the high-level signal of the first node n1 is written into the second node n2, and stored in the third capacitor C3, to cause the eighth transistor T8 to be turned off. The seventh transistor T7 is turned on, and the low-level signal of the third voltage terminal V3 is written into the fifth node n5, and stored in the second capacitor C2, to cause the tenth transistor T10 to be turned on. The high-level signal of the fifth voltage terminal V5 is written into the output terminal Gout, and the shift register outputs a high-level signal.

In the input terminal Input there is a high-level signal, in the first clock-signal line CA there is a low-level signal, and in the second clock-signal line CB there is a high-level signal. The first transistor T1 is turned on, and the high-level signal of the input terminal Input is written into the first node n1, and stored in the fourth capacitor C4. The eleventh transistor T11 is turned off, and the second node n2 maintains the high level by the effect of the third capacitor C3, to cause the eighth transistor T8 to be turned off. The second transistor T2 is turned on, and the low-level signal of the second voltage terminal V2 is written into the fourth node n4, and stored in the first capacitor C1. The seventh transistor T7 is turned off, and the fifth node n5 maintains the low level by the effect of the second capacitor C2, to cause the tenth transistor T10 to be turned on. The high-level signal of the fifth voltage terminal V5 is written into the output terminal Gout, and the shift register outputs a high-level signal.

At the third stage t3, in the input terminal Input there is a high-level signal, in the first clock-signal line CA there is a high-level signal, and in the second clock-signal line CB there is a low-level signal. The second transistor T2 is turned off, and the fourth node n4 maintains the low level by the effect of the first capacitor C1, to cause the third transistor T3 and the sixth transistor T6 to be turned on. The fifth transistor T5 is turned on, and the high-level signal of the sixth voltage terminal V6 is written into the first node n1. The eleventh transistor T11 is turned on, and the high-level signal of the first node n1 is written into the second node n2, and stored in the third capacitor C3, to cause the eighth transistor T8 to be turned off. The seventh transistor T7 is turned on, and the low-level signal of the third voltage terminal V3 is written into the fifth node n5, and stored in the second capacitor C2, to cause the tenth transistor T10 to be turned on. The high-level signal of the fifth voltage terminal V5 is written into the output terminal Gout, and the shift register outputs a high-level signal.

At the fourth stage t4, in the input terminal Input there is a low-level signal, in the first clock-signal line CA there is a low-level signal, and in the second clock-signal line CB there is a high-level signal. The first transistor T1 is turned on, and the low-level signal of the input terminal Input is written into the first node n1, and stored in the fourth capacitor C4, to cause the ninth transistor T9 to be turned on. The high-level signal of the fourth voltage terminal V4 is written into the fifth node n5, and stored in the second capacitor C2, to cause the tenth transistor T10 to be turned off. The second transistor T2 is turned on, and the low-level signal of the second voltage terminal V2 is written into the fourth node n4, and stored in the first capacitor C1. The second node n2 leaks electric charges to the first node n1 via the eleventh transistor T11, to cause the electrical level of the second node n2 to be reduced, thereby causing the electric potential of the output terminal Gout to be reduced.

At the fifth stage t5, in the input terminal Input there is a low-level signal, in the first clock-signal line CA there is a high-level signal, and in the second clock-signal line CB there is a low-level signal. The first node n1 maintains the low level by the effect of the fourth capacitor C4, to cause the fourth transistor T4, the ninth transistor T9 and the eleventh transistor T11 to be turned on. After the fourth transistor T4 has been turned on, the high-level signal of the third clock-signal terminal CK3 is written into the fourth node n4, and stored in the first capacitor C1, to cause the third transistor T3 and the sixth transistor T6 to be turned off. After the ninth transistor T9 has been turned on, the high-level signal of the fourth voltage terminal V4 is written into the fifth node n5, and stored in the second capacitor C2. After the eleventh transistor T11 has been turned on, the electrical level of the second node n2 is reduced by the effect of the fourth capacitor C4, and stored in the third capacitor C3, to cause the eighth transistor T8 to be turned on. The low-level signal of the first voltage terminal V1 is written into the output terminal Gout, to cause the shift register to output a low-level signal.

Within the second period:

At the first stage t1, in the input terminal Input there is a high-level signal, in the first clock-signal line CA there is a low-level signal, and in the second clock-signal line CB there is a high-level signal. The fifth node n5, at the sixth stage t6 of the first period, stores a high-level signal, to cause the tenth transistor T10 to be turned off. The second transistor T2 is turned on, and the low-level signal of the second voltage terminal V2 is written into the fourth node n4, and stored in the first capacitor C1. The first transistor T1 is turned on, and the high-level signal of the input terminal Input is written into the first node n1. The eleventh transistor T11 is turned off, and the first node n1 and the second node n2 are disconnected from each other. The third capacitor C3, at the sixth stage t6 of the first period, stores a low-level signal; in other words, the second node n2 maintains the low-level signal by the effect of the third capacitor C3, to cause the eighth transistor T8 to be turned on. The low-level signal of the first voltage terminal V1 is written into the output terminal Gout, to cause the shift register to output a low-level signal.

Accordingly, it can be known that, at the first stage t1, the high-level signal of the input terminal Input is written into the first node n1, and the first node n1 and the second node n2 are disconnected by the effect of the isolating circuit 50, whereby the second node n2 can maintain the low-level signal written in the preceding period. Therefore, the first outputting circuit 40 is controlled, so that the electrical level of the first voltage terminal V1 is written into the output terminal Gout, to prevent floating of the output terminal Gout at the first stage t1, which increases the output stability of the shift register.

FIG. 16 schematically shows a block diagram of the steps of a driving method of a shift register. As shown in FIG. 16, the driving method of a shift register comprises the following steps:

S100: at the first stage, supplying signals to the first clock-signal terminal and the second clock-signal terminal, whereby a first electrical level of the input terminal is written into the first node, and the path between the first node and the second node is disconnected.

As an example, at the first stage, the signal of the input terminal is a high-level signal, a low-level signal is supplied to the first clock-signal terminal, and a high-level signal is supplied to the second clock-signal terminal. The first transistor is switched on, and the high-level signal of the input terminal is written into the first node. The eleventh transistor is turned off, the path between the first node and the second node is disconnected, and the second node may maintain the low-level signal written within the preceding period by the effect of the third capacitor. The eighth transistor is turned on under the controlling by the low-level signal of the second node, to cause the low level of the first voltage terminal to be written into the output terminal.

S200: at the second stage and the third stage, supplying signals to the first clock-signal terminal and the second clock-signal terminal, whereby the first node and the second node are connected, and an electrical level of the first node is written into the second node.

As an example, the second stage may comprise sequentially a first half stage and a second half stage. At the first half stage, the signal of the input terminal is a high-level signal, a high-level signal is supplied to the first clock-signal terminal, and a low-level signal is supplied to the second clock-signal terminal. The second transistor is turned off, the fourth node maintains the low level by the effect of the first capacitor, to cause the sixth transistor to be turned on, and the fifth transistor to be turned on, and the high-level signal of the sixth voltage terminal is written into the first node, and stored in the fourth capacitor. The eleventh transistor is turned on, and the high-level signal of the first node is written into the second node, and stored in the third capacitor.

As an example, at the second half stage, the signal of the input terminal is a high-level signal, a low-level signal is supplied to the first clock-signal terminal, and a high-level signal is supplied to the second clock-signal terminal. The first transistor is turned on, and the high-level signal of the input terminal is written into the first node, and stored in the fourth capacitor. The eleventh transistor is turned off, and the path between the second node and the first node is disconnected.

As an example, the third stage may repeat the first half stage of the second stage.

S300: at the fourth stage, supplying signals to the first clock-signal terminal and the second clock-signal terminal, whereby a second electrical level of the input terminal is written into the first node, and the path between the first node and the second node is disconnected.

As an example, at the fourth stage, the signal of the input terminal is a low-level signal, a low-level signal is supplied to the first clock-signal terminal, and a high-level signal is supplied to the second clock-signal terminal. The first transistor is switched on, and the low-level signal of the input terminal is written into the first node. The eleventh transistor is turned off, and the path between the first node and the second node is disconnected.

S400: at the fifth stage, supplying a signal to the second clock-signal terminal, whereby the path between the first node and the second node is connected, and the electrical level of the first node is written into the second node.

As an example, at the fifth stage, the second clock-signal terminal is supplied with a low-level signal, the eleventh transistor is turned on, the path between the first node and the second node is conducted, and the low-level signal of the first node is written into the second node.

In the driving method of a shift register according to the embodiments of the present disclosure, at the first stage, the high-level signal of the input terminal is written into the first node, and the second node, by the effect of the isolating circuit, is disconnected from the first node, whereby the electrical level of the second node is not influenced by the first node, and the second node can maintain the low-level signal written in the preceding period. Therefore, the first outputting circuit is controlled, so that the electrical level of the first voltage terminal is written into the output terminal, to prevent floating of the output terminal at the first stage, which increases the output stability of the shift register.

The above are merely particular embodiments of the present disclosure, and the protection scope of the present disclosure is not limited thereto. All of the variations or substitutions that a person skilled in the art can easily envisage within the technical scope disclosed by the present disclosure should fall within the protection scope of the present disclosure. Therefore, the protection scope of the present disclosure should be subject to the protection scope of the claims.

1. A shift register, wherein the shift register comprises an inputting circuit, an isolating circuit, a resetting circuit, a first controlling circuit and an outputting circuit;
the inputting circuit is electrically connected to an input terminal, a first clock-signal terminal and a first node, and the inputting circuit is configured for, under controlling by a signal of the first clock-signal terminal, writing a signal of the input terminal into the first node;
the isolating circuit is electrically connected to the first node, a second node and a second clock-signal terminal, and the isolating circuit is configured for, under controlling by a signal of the second clock-signal terminal, connecting or disconnecting a path between the first node and the second node;
the resetting circuit is electrically connected to a first voltage terminal, an output terminal and the second node, and the resetting circuit is configured for, under controlling by a signal of the second node, writing an electrical level of the first voltage terminal into the output terminal;
the first controlling circuit is electrically connected to a fourth node, a fourth clock-signal terminal, a third voltage terminal, the first node, a fourth voltage terminal and a fifth node, and the first controlling circuit is configured for, under controlling by signals of the fourth node and the fourth clock-signal terminal, writing an electrical level of the third voltage terminal into the fifth node; or, under controlling by the signal of the first node, writing an electrical level of the fourth voltage terminal into the fifth node; and
the outputting circuit is electrically connected to a fifth voltage terminal, the output terminal and the fifth node, and the outputting circuit is configured for, under controlling by a signal of the fifth node, writing an electrical level of the fifth voltage terminal into the output terminal.

2. The shift register according to claim 1, wherein the isolating circuit comprises a storing sub-circuit and a switch sub-circuit;
the storing sub-circuit is electrically connected to the first node, and the storing sub-circuit is configured for storing the signal of the first node; and
the switch sub-circuit is electrically connected to the second clock-signal terminal, the first node and the second node, and the switch sub-circuit is configured for, under controlling by the signal of the second clock-signal terminal, connecting or disconnecting the path between the first node and the second node.

3. The shift register according to claim 2, wherein the switch sub-circuit comprises an eleventh transistor; and
a control electrode of the eleventh transistor is electrically connected to the second clock-signal terminal, a first electrode of the eleventh transistor is electrically connected to the second node, and a second electrode of the eleventh transistor is electrically connected to the first node.

4. The shift register according to claim 1, wherein the storing sub-circuit comprises a fourth capacitor, and a first polar plate of the fourth capacitor is electrically connected to the first node.

5. The shift register according to claim 1, wherein the shift register further comprises a second controlling circuit, the second controlling circuit is electrically connected to a fifth clock-signal terminal, the fourth node, a sixth voltage terminal and the first node, and the second controlling circuit is configured for, under controlling by signals of the fifth clock-signal terminal and the fourth node, writing an electrical level of the sixth voltage terminal into the first node.

6. The shift register according to claim 5, wherein the second controlling circuit comprises a fifth transistor and a sixth transistor;
a control electrode of the fifth transistor is electrically connected to the fifth clock-signal terminal, a first electrode of the fifth transistor is electrically connected to the first node, and a second electrode of the fifth transistor is electrically connected to a third node; and
a control electrode of the sixth transistor is electrically connected to the fourth node, a first electrode of the sixth transistor is electrically connected to the third node, and a second electrode of the sixth transistor is electrically connected to the sixth voltage terminal.

7. The shift register according to claim 1, wherein the shift register further comprises a second controlling circuit, the second controlling circuit is electrically connected to a fifth clock-signal terminal, the fourth node, a sixth voltage terminal and the second node, and the second controlling circuit is configured for, under controlling by signals of the fifth clock-signal terminal and the fourth node, writing an electrical level of the sixth voltage terminal into the second node.

8. The shift register according to claim 7, wherein the second controlling circuit comprises a fifth transistor and a sixth transistor;
a control electrode of the fifth transistor is electrically connected to the fifth clock-signal terminal, a first electrode of the fifth transistor is electrically connected to the second node, and a second electrode of the fifth transistor is electrically connected to a third node; and
a control electrode of the sixth transistor is electrically connected to the fourth node, a first electrode of the sixth transistor is electrically connected to the third node, and a second electrode of the sixth transistor is electrically connected to the sixth voltage terminal.

9. The shift register according to claim 1, wherein the shift register further comprises a third controlling circuit, the third controlling circuit is electrically connected to a third clock-signal terminal, the first node, a second voltage terminal and the fourth node, and the third controlling circuit is configured for, under controlling by a signal of the third clock-signal terminal, writing an electrical level of the second voltage terminal into the fourth node; or, under controlling by the signal of the first node, writing a signal of the third clock-signal terminal into the fourth node.

10. The shift register according to claim 9, wherein the third controlling circuit comprises a second transistor and a fourth transistor;
a control electrode of the second transistor is electrically connected to the third clock-signal terminal, a first electrode of the second transistor is electrically connected to the second voltage terminal, and a second electrode of the second transistor is electrically connected to the fourth node; and
a control electrode of the fourth transistor is electrically connected to the first node, a first electrode of the fourth transistor is electrically connected to the third clock-signal terminal, and a second electrode of the fourth transistor is electrically connected to the fourth node.

11. The shift register according to claim 1, wherein the inputting circuit comprises a first transistor, a control electrode of the first transistor is electrically connected to the first clock-signal terminal, a first electrode of the first transistor is electrically connected to the first node, and a second electrode of the first transistor is electrically connected to the input terminal.

12. The shift register according to claim 1, wherein the resetting circuit comprises an eighth transistor and a third capacitor;
a control electrode of the eighth transistor is electrically connected to the second node, a first electrode of the eighth transistor is electrically connected to the first voltage terminal, and a second electrode of the eighth transistor is electrically connected to the output terminal; and
a first polar plate of the third capacitor is electrically connected to the second node, and a second polar plate of the third capacitor is electrically connected to the second clock-signal terminal, the first voltage terminal or the output terminal.

13. The shift register according to claim 1, wherein the outputting circuit comprises a tenth transistor and a second capacitor;
a control electrode of the tenth transistor is electrically connected to the fifth node, a first electrode of the tenth transistor is electrically connected to the output terminal, and a second electrode of the tenth transistor is electrically connected to the fifth voltage terminal; and
a first polar plate of the second capacitor is electrically connected to the fifth node, and a second polar plate of the second capacitor is electrically connected to the fifth voltage terminal.

14. The shift register according to claim 1, wherein the first controlling circuit comprises a third transistor, a seventh transistor and a first capacitor;
a control electrode of the third transistor is electrically connected to the fourth node, a first electrode of the third transistor is electrically connected to a sixth node, and a second electrode of the third transistor is electrically connected to the third voltage terminal;
a control electrode of the seventh transistor is electrically connected to the fourth clock-signal terminal, a first electrode of the seventh transistor is electrically connected to the sixth node, and a second electrode of the seventh transistor is electrically connected to the fifth node; and
a first polar plate of the first capacitor is electrically connected to the fourth node, and a second polar plate of the first capacitor is electrically connected to the second clock-signal terminal.

15. A driving method of a shift register, for driving the shift register according to claim 1, wherein an operation cycle of the shift register comprises a first stage, a second stage, a third stage, a fourth stage and a fifth stage, and the driving method comprises:
at the first stage, supplying signals to the first clock-signal terminal and the second clock-signal terminal, whereby a first electrical level of the input terminal is written into the first node, and the path between the first node and the second node is disconnected;
at the second stage and the third stage, supplying signals to the first clock-signal terminal and the second clock-signal terminal, whereby the first node and the second node are connected, and an electrical level of the first node is written into the second node;
at the fourth stage, supplying signals to the first clock-signal terminal and the second clock-signal terminal, whereby a second electrical level of the input terminal is written into the first node, and the path between the first node and the second node is disconnected; and
at the fifth stage, supplying a signal to the second clock-signal terminal, whereby the path between the first node and the second node is connected, and the electrical level of the first node is written into the second node;
wherein the first electrical level is greater than the second electrical level.

16. A gate driving circuit, wherein the gate driving circuit comprises a plurality of instances of the shift register according to claim 1, and the plurality of shift registers are cascaded sequentially.

17. A display panel, wherein the display panel comprises the gate driving circuit according to claim 16.

18. A displaying device, wherein the displaying device comprises the display panel according to claim 17.
